(19) United States
(12) Patent Application Publication
(10) Pub. No.: US 2024/0206168 A1
(43) Pub. Date: Jun. 20, 2024

(54) CONTACT STRUCTURE AND A GATE LINE SLIT AND MERGE METHOD TO FORM THEREOF

(71) Applicant: Yangtze Memory Technologies Co., Ltd., Wuhan (CN)

(72) Inventors: Zuixin ZENG, Wuhan (CN); Xianghui ZHAO, Wuhan (CN); Junxiong WANYAN, Wuhan (CN); Chuan ZHANG, Wuhan (CN); Haiqing DOU, Wuhan (CN)

(73) Assignee: Yangtze Memory Technologies Co., Ltd., Wuhan (CN)

(21) Appl. No.: 18/318,993

(22) Filed: May 17, 2023

Related U.S. Application Data
(60) Provisional application No. 63/433,284, filed on Dec. 16, 2022.

(30) Foreign Application Priority Data
Apr. 23, 2023 (CN) 2023104474881

(51) Int. Cl. H10B 43/27; H10B 43/10

(52) U.S. Cl. CPC H10B 43/27; H10B 43/10

(57) ABSTRACT

Aspects of the disclosure provide a semiconductor device. The semiconductor device includes a substrate and a stack of alternative layers including insulating layers and gate layers that are stacked alternatively over the substrate. The stack of alternative layers includes an array region and a contact region. The semiconductor device includes channel structures disposed through the stack of alternative layers in the array region. Each channel structure forms a stack of transistors in a series configuration with the gate layers being gate terminals of the stack of transistors. The semiconductor device includes contact structures disposed in the contact region.

Each contact structure electrically connects to one of the gate layers. The semiconductor device includes gate line trenches disposed through the stack of alternative layers in the array region and in the contact region. The gate line trenches are formed during the formation of the contact structures in the contact region.

### INCORPORATION BY REFERENCE

The present disclosure claims the benefits of China patent application No. 2023104474881, filed on Apr. 23, 2023, and U.S. Provisional Application No. 63/433,284, filed on Dec. 16, 2022. All disclosures of the prior applications are incorporated herein by reference in their entirety.

### TECHNICAL FIELD

The present disclosure relates to a three-dimensional memory device, and specifically relates to a staircase contact and gate line structure.

### BACKGROUND

Vertical device technologies, such as three dimensional (3D) NAND flash memory technology, and the like can achieve higher data storage density without requiring smaller memory cells. In some examples, a 3D NAND memory device includes a core region and a staircase region. The core region includes a stack of alternating gate layers and insulating layers. The stack of alternating gate layers and insulating layers is used to form memory cells that are stacked vertically. The staircase region includes the respective gate layers in the stair-step form to facilitate forming contact structures to the respective gate layers. The contact structures are used to connect driving circuitry to the respective gate layers for controlling the stacked memory cells.

### SUMMARY

Aspects of the disclosure provide a semiconductor device. The semiconductor device includes a substrate and a stack of alternative layers including insulating layers and gate layers that are stacked alternatively over the substrate. The stack of alternative layers includes an array region and a contact region. The semiconductor device includes channel structures disposed through the stack of alternative layers in the array region. Each channel structure forms a stack of transistors in a series configuration with the gate layers being gate terminals of the stack of transistors. The semiconductor device includes contact structures disposed in the contact region. Each contact structure electrically connects to one of the gate layers. The semiconductor device includes gate line trenches disposed through the stack of alternative layers in the array region and in the contact region. The gate line trenches are formed during the formation of the contact structures in the contact region.

In an embodiment, the semiconductor device includes one or more sacrificial layers underneath the plurality of contact structures.

In an embodiment, each of the contact structures includes a first spacer layer on a sidewall of the respective contact structure.

In an embodiment, each of the gate line trenches includes a second spacer layer on a sidewall of the respective gate line trench.

In an embodiment, a ratio between a critical dimension of each of the plurality of contact structures and a critical dimension of each of the plurality of gate line trenches is less than or equal to a threshold. In an example, the threshold is between 0.5 and 1.5.

Aspects of the disclosure provide a method of manufacturing a semiconductor device. Under the method, insulating layers and sacrificial layers are stacked alternatively over a substrate of the semiconductor device to form a stack of alternative layers that includes an array region and a contact region. The array region is used for forming transistors, and the contact region is used for forming contact structures to electrically connect gate terminals of the transistors. Gate line trenches are formed in the array region and in the contact region during the formation of the contact structures in the contact region. At least a part of the sacrificial layers is replaced with gate layers through the gate line trenches. The gate layers are the gate terminals of the transistors and electrically connecting to the contact structures.

In an embodiment, for each of the contact structures in the contact region, a contact hole is formed through a subset of the stack of alternative layers in the contact region. A bottom of the contact hole is one of the sacrificial layers. A first spacer layer is formed on a sidewall and the bottom of the contact hole. The first spacer layer is removed on the bottom of the contact hole. A portion of the one of the sacrificial layers is removed to form a first open space in the one of the sacrificial layers. A conductive material is filled into the first open space resulted from the removed portion of the one of the sacrificial layers to form a conductive pad of the respective contact structure. The conductive material is filled into the contact hole to form the respective contact structure.

In an embodiment, the first spacer layer on the sidewall of the contact hole is kept during the removing of the first spacer layer on the bottom of the contact hole.

In an embodiment, the first spacer layer includes silicon oxide and the conductive material includes tungsten.

In an embodiment, the gate line trenches are formed in the array region and in the contact region during the formation of the contact holes. The gate line trenches and the contact holes are formed under a same etching process in which a same number of etching steps is used in the formation of a contact hole with a maximum depth among the contact holes and the formation of the gate line trenches.

In an embodiment, before forming the first spacer layer, the gate line trenches and the contact holes are filled with a sacrificial material. The sacrificial material inside the contact holes in the contact region is removed.

In an embodiment, the sacrificial material includes poly silicon.

In an embodiment, the sacrificial material inside the gate line trenches in the contact region is removed. Through the gate line trenches in the contact region, the sacrificial layers adjacent to the gate line trenches in the contact region is removed, until all the conductive pads of the contact structures are open for connecting the gate layers. The conductive material is filled into second open spaces resulted from the removed sacrificial layers to form a first portion of the gate layers so that the first portion of the gate layers electrically connects to the conductive pads of the contact structures.

In an embodiment, at least a portion of the sacrificial layers underneath the conductive pads of the contact structures is kept during the removing of the sacrificial layers adjacent to the gate line trenches in the contact region.

In an embodiment, the sacrificial material inside the gate line trenches in the array region is removed. Through the gate line trenches in the array region, the sacrificial layers in the array region is removed. The conductive material is filled into third open spaces resulted from the removed sacrificial layers in the array region to form a second portion of the gate layers so that the second portion of the gate layers electrically connects to the first portion of the gate layers.

In an embodiment, the gate line trenches in the array region and in the contact region are filled with one or more dielectric materials.

In an embodiment, for each gate line trench, a second spacer layer is formed on a sidewall and a bottom of the respective gate line trench. A dielectric material is filled into the respective gate line trench.

In an embodiment, a ratio between a critical dimension of each of the contact structures and a critical dimension of each of the gate line trenches is less than or equal to a threshold.

In an embodiment, the threshold is between 0.5 and 1.5.

Aspects of the disclosure provided a memory system. The memory system includes one or more memory devices and a memory controller that is coupled to and controls the one or more memory devices. Each of the one or more memory devices includes a substrate and a stack of alternative layers including insulating layers and gate layers that are stacked alternatively over the substrate. The stack of alternative layers includes an array region and a contact region. Each of the one or more memory devices includes a plurality of channel structures disposed through the stack of alternative layers in the array region. Each channel structure forms a stack of transistors in a series configuration with the gate layers being gate terminals of the stack of transistors, Each of the one or more memory devices includes a plurality of contact structures disposed in the contact region, each contact structure electrically connecting to one of the gate layers, and a plurality of gate line trenches disposed through the stack of alternative layers in the array region and in the contact region. The gate line trenches are formed during the formation of the plurality of contact structures in the contact region.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a vertical cross-sectional view of an exemplary vertical memory device 100 according to an embodiment of the disclosure.

FIG. 2 illustrates a vertical cross-sectional view of an exemplary vertical memory device 200 implemented under a staircase-contact (SCT) architecture according to an embodiment of the disclosure.

FIG. 3A illustrates a horizontal cross-sectional view of an exemplary vertical memory device 300 fabricated using a merge formation process provided in this disclosure.

FIGS. 3B-3D illustrate vertical cross-sectional views of the vertical memory device 300 along dashed line AA′, BB′, and CC′, respectively.

FIGS. 4A-4D illustrate a first contact hole etching step of the merge formation process according to certain embodiments of the disclosure.

FIGS. 5A-5D illustrate a second contact hole etching step of the merge formation process according to certain embodiments of the disclosure.

FIGS. 6A-6D illustrate a third contact hole etching step of the merge formation process according to certain embodiments of the disclosure.

FIGS. 7A-7D illustrate a last contact hole etching step of the merge formation process according to certain embodiments of the disclosure.

FIGS. 8A-8D illustrate vertical cross-sectional views of the device 300 after ae sacrificial material filling step of the merge formation process along the dashed lines AA′ (in the Y-Z plane), BB′ (in the Y-Z plane), DD′ (in the Y-Z plane), and CC′ (in the X-Z plane), respectively.

FIGS. 9A-9F illustrate a contact structure forming step of the merge formation process according to certain embodiments of the disclosure.

FIGS. 10A-10C illustrate a contact structure connecting step of the merge formation process according to certain embodiments of the disclosure.

FIGS. 11A-11C illustrate a gate layer forming step of the merge formation process according to certain embodiments of the disclosure.

FIG. 12 illustrates a flowchart outlining an exemplary manufacturing process for fabricating the vertical memory device 300 according to certain embodiments of the disclosure.

FIG. 13 illustrates an exemplary electronic system 1300 according to certain embodiments of the disclosure.

FIG. 14A illustrates an exemplary memory card 1400 according to certain embodiments of the disclosure.

FIG. 14B illustrates an exemplary solid state drive device 14450 according to certain embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In this disclosure, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, as used herein, the words “a,” “an” and the like generally carry a meaning of “one or more,” unless stated otherwise.

Furthermore, the terms “approximately,” “approximate,” “about,” and similar terms generally refer to ranges that include the identified value within a margin of 20%, 10%, or preferably 5%, and any values therebetween.

According to aspects of the disclosure, a vertical memory device (e.g., 3D NAND memory) can include a memory array region and a contact region. The memory array region can be formed over a first region of a substrate of the vertical memory device. The contact region can be formed over a second region of the substrate of the vertical memory device to connect memory cells in the memory array region to peripheral circuitry of the vertical memory device.

The memory array region can include gate layers and insulating layers that are disposed over the first region of the substrate of the vertical memory device to form a stack of gate layers and insulating layers. In an embodiment, the gate layers and insulating layers can be alternatively stacked to form the stack of alternating gate layers and insulating layers. However, other sequences or combinations of the gate layers and insulating layers can be utilized in this disclosure. The gate layers can include one or more gate stack materials, such as high dielectric constant (high-k) gate material, a metal gate (MG) electrode, and the like. The insulating layers can be made of one or more insulating materials, such as silicon nitride, silicon dioxide, and/or the like.

The memory array region of the vertical memory device can include a plurality of channel structures that is disposed over the first region of the substrate. Each channel structure can extend through the gate layers and insulating layers in order to form a stack of transistors in a series configuration with the gate layers being gate terminals of the stack of transistors. The stack of transistors forms a memory cell string of the vertical memory device. The memory cell string can include, for example, a plurality of memory cells, a string selection transistor, and a ground selection transistor that are disposed in series in a vertical direction with respect to a main surface of the substrate. Each of the plurality of memory cells can store data.

In this disclosure, a main surface of the substrate of the vertical memory device extends in the X direction and the Y direction. An X-Y plane, which is parallel to the main surface of the substrate, is referred to as a horizontal cross-section of the vertical memory device. An X-Z plane or a Y-Z plane, which is perpendicular to the main surface of the substrate, is referred to as a vertical cross-section of the vertical memory device.

In an embodiment, each of the channel structures can have a pillar shape that extends in the Z direction. The channel structures can be disposed separately from each other along the X direction or the Y direction. The channel structures can also be disposed in any suitable array shape, such as a matrix array shape along the X direction and the Y direction, a zig-zag array shape along the X or Y direction, a beehive (e.g., hexagonal) array shape, and/or the like. In an example, each channel structure can have a circular or an oval shape in the X-Y plane, and a pillar shape in the X-Z plane.

In an embodiment, each of the channel structures can be formed of a plurality of materials. For example, each channel structure can include a gate dielectric layer, a semiconductor layer, and an insulating layer. These layers can also have the circular or oval shape in the X-Y plane, and extend in the Z direction. The gate dielectric layer can be formed on the sidewall of the channel structure, and can include multiple sub-layers, such as a tunnel insulating sub-layer (e.g., formed of silicon oxide), a charge storage sub-layer (e.g., formed of silicon nitride), and a blocking insulating sub-layer (e.g., formed of silicon oxide). These sub-layers can be sequentially stacked from the sidewall. In an example, the gate dielectric layer can have an oxide-nitride-oxide (ONO) stack structure. The semiconductor layer can be formed of any suitable semiconductor material, such as polysilicon or monocrystalline silicon, and the semiconductor material may be un-doped or may include a p-type or n-type dopant. The insulating layer can be formed of any insulating material, such as silicon oxide and/or silicon nitride, and/or may be formed as an air gap.

Various fabrication technologies, such as gate-first fabrication technology, gate-last fabrication technology, and the like can be used to fabricate vertical memory devices. The gate-first fabrication technology forms the gates of the memory cells earlier than the channel structures of the memory cells. The gate-last fabrication technology uses sacrificial layers (also referred to as dummy gate layers) to facilitate a formation of the channel structures of the memory cells, and replaces the sacrificial layers with the gates of the memory cells after the formation of the channel structures. To replace the sacrificial layers with the gates, the sacrificial layers are removed and the gate layers are subsequently formed.

According to aspects of the disclosure, the stack of gate layers and insulating layers can extend to the contact region of the vertical memory device to connect the memory cells in the memory array region to the peripheral circuitry. The peripheral circuitry can include, for example, an address decoder, a driving circuitry, a sense amplifier, and/or the like. The contact region can include contact structures connecting the respective gates of the stack of transistors in the memory array region to the peripheral circuitry, which includes but is not limited to word line driving circuitry, ground selection driving circuitry, string selection driving circuitry, and the like.

In an embodiment, the stack of gate layers and insulating layers in the contact region can be formed in a stair-step shape over the second region of the substrate. In such a case, the contact region can be referred to as a staircase region of the vertical memory device. Each contact structure in the staircase region can be disposed on one of the stair-steps to connect the respective gate layer.

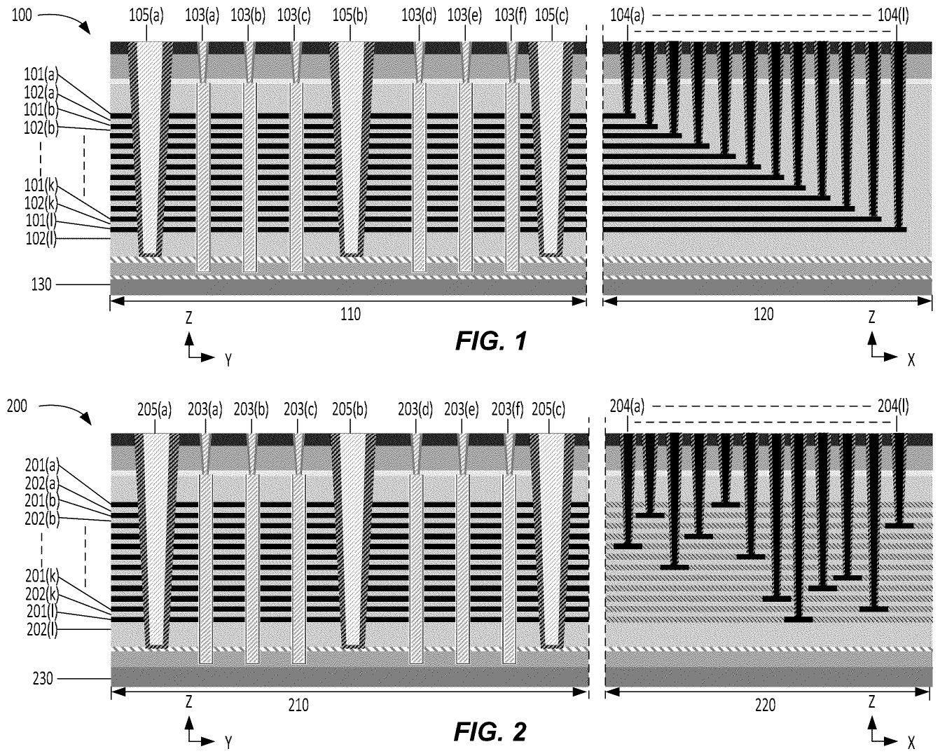

FIG. 1 illustrates vertical cross-sectional views of an exemplary vertical memory device 100 according to an embodiment of the disclosure. The vertical memory device 100 includes a memory array region 110 and a contact region 120. The memory array region 110 and the contact region 120 are formed over a first region and a second region of a substrate 130 of the vertical memory device 100, respectively. The cross-sectional views of the memory array region 110 and the contact region 120 are in Y-Z and X-Z planes, respectively.

The memory array region 110 includes a stack of alternating gate layers 101(a)-101(l) and insulating layers 102(a)-102(l). The memory array region 110 also includes channel structures 103(a)-103(f). Each of the channel structures 103(a)-103(f) can extend through the gate layers 101(a)-101(l) and insulating layers 102(a)-102(l) in order to form a stack of transistors in a series configuration.

In an embodiment, the stack of transistors can include a string selection transistor, a gate of a ground selection transistor, and a plurality of memory cells that is stacked with the ground selection transistor and the string selection transistor.

In an embodiment, the gate layer 101(a) can correspond to a gate of the string selection transistor, the gate layer 101(l) can correspond to a gate of the ground selection transistor, and the other gate layers 101(b)-101(k) can correspond to gates of the plurality of memory cells. The gate layers 101(b)-101(k) can also be referred to as word lines of the vertical memory device 100.

In an embodiment, a stack of alternating sacrificial layers and insulating layers is first formed in the vertical memory device 100, and the sacrificial layers are then removed and replaced with the gate layers 101(a)-101(l) through gate line slits 105(a)-105(c).

Still referencing to FIG. 1, the stack of alternating gate layers 101(a)-101(l) and insulating layers 102(a)-102(l) extends to the contact region 120 of the vertical memory device 100 and is formed in a stair-step shape over the second region of the substrate 130. Contact structures 104(a)-104(l) in the contact region 120 are disposed over the second region of the substrate 130. Each contact structure is disposed on one of the stair-steps to connect the respective gate layer. For example, the contact structure 104(a) connects to the gate layer 101(a), and so on.

It is noted that, in the vertical memory device 100, the stair-step shape of the contact region 120 has to be formed before the contact structures 104(a)-104(l) are formed, in order for the contact structures 104(a)-104(l) to be disposed on the stair-steps. That is, the stair-steps and the contact structures 104(a)-104(l) in the contact region 120 are formed in different fabrication process steps.

In order to reduce the fabrication cost and to simplify the fabrication process flow, the present disclosure provides a staircase-contact (SCT) architecture in which the contact structures are formed to connect the gate layers without forming the stair-steps in the contact region.

FIG. 2 illustrates vertical cross-sectional views of an exemplary vertical memory device 200 implemented under the SCT architecture according to an embodiment of the disclosure. Similar to the vertical memory device 100, the vertical memory device 200 includes a memory array region 210 and a contact region 220. The memory array region 210 and the contact region 220 are formed over a first region and a second region of a substrate 230 of the vertical memory device 200, respectively. The cross-sectional views of the memory array region 210 and the contact region 220 are in Y-Z and X-Z planes, respectively.

The memory array region 210 includes a stack of alternating gate layers 201(a)-201(l) and insulating layers 202(a)-202(l). The memory array region 210 also includes channel structures 203(a)-203(f). Each of the channel structures 203(a)-203(f) can extend through the gate layers 201(a)-201(l) and insulating layers 202(a)-202(l) in order to form a stack of transistors in a series configuration.

The stack of alternating gate layers 201(a)-201(l) and insulating layers 202(a)-202(l) extends to the contact region 220. Contact structures 204(a)-204(l) in the contact region 220 are disposed over the second region of the substrate 230. Each contact structure is disposed to connect one of the gate layers 201(a)-201(l). For example, the contact structure 204(a) is disposed to connect the gate layer 201(e), and so on.

It is noted that, under the SCT architecture, the contact structures 204(a)-204(l) of the vertical memory device 200 can be formed to connect the gate layers 201(a)-201(l) without forming stair-steps in the stack of alternating gate layers 201(a)-201(l) and insulating layers 202(a)-202(l) in the contact region 220. Thus, the fabrication process flow can be simplified and the fabrication cost can be reduced.

In an embodiment, a stack of alternating sacrificial layers and insulating layers can be first formed, and each of the contact structures 204(a)-204(l) is then disposed on the respective sacrificial layer. After the contact structures 204(a)-204(l) are formed, the sacrificial layers are removed and replaced with the gate layers 201(a)-201(l) through gate line slits 205(a)-205(c).

In an embodiment, a stack of alternating sacrificial layers and insulating layers can be first formed. Then, the sacrificial layers can be removed and replaced with the gate layers 201(a)-201(l) through the gate line slits 205(a)-205(c). A plurality of contact holes can be formed in the contact region 220 after the replacement of the sacrificial layers with the gate layers. The contact structures 204(a)-204(l) can be formed through the plurality of contact holes.

In an embodiment, a stack of alternating sacrificial layers and insulating layers can be first formed. Then, a plurality of contact holes can be formed in the contact region 220. After the plurality of contact holes are formed, the sacrificial layers can be removed and replaced with the gate layers 201(a)-201(l) through the gate line slits 205(a)-205(c), and the contact structures 204(a)-204(l) can be formed through the plurality of contact holes.

In an example, a critical dimension (or a smallest possible feature size in lithography) of a gate line slit is around 100-200 nm, and a critical dimension of a contact structure is around 1-2 μm. Since a size difference between these two critical dimensions is too large, the gate line slit and the contact structure have to be formed in different fabrication processes.

In order to further reduce the fabrication cost and to simplify the fabrication process flow, the present disclosure provides a method and a process of merging the formation of the gate line slits with the formation of the contact structures in the contact region, such that the gate line slits can be formed during the formation of the contact structures in the contact region. The method (or process) can be referred to as a merge formation method (or a merge formation process) in this disclosure.

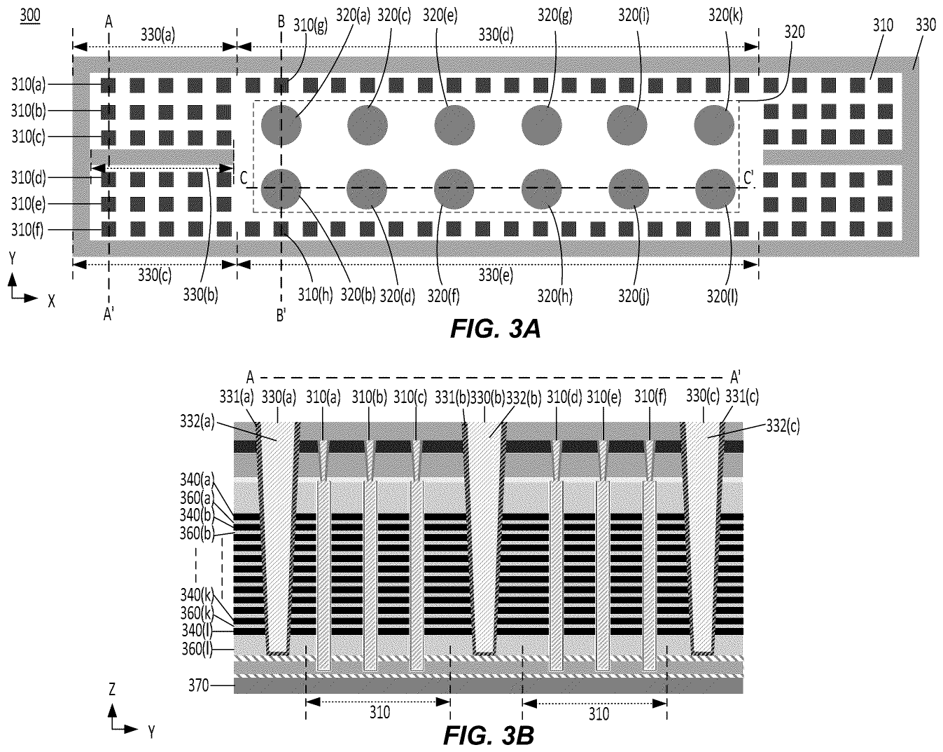

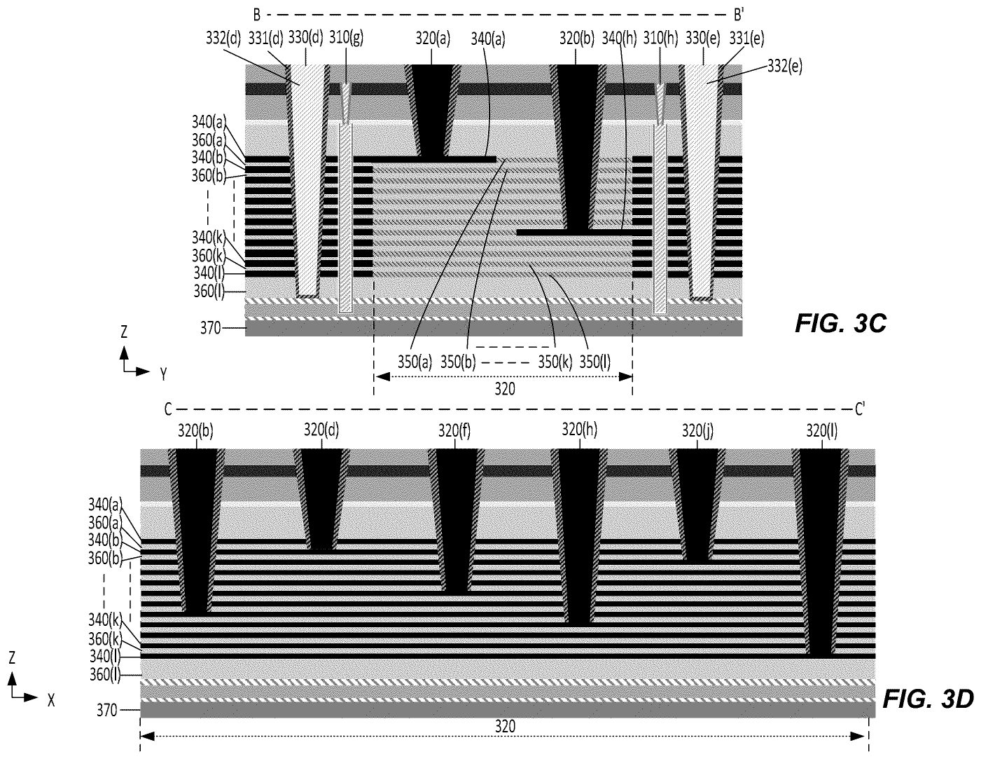

FIG. 3A illustrates a horizontal cross-sectional view of an exemplary vertical memory device 300 fabricated using the merge formation process provided in this disclosure. The vertical memory device 300 includes a memory array region 310, a contact region 320, and a gate line slit region 330. In the X-Y plane, the gate line slit region 330 encloses the memory array region 310 and the contact region 320. It is noted that shapes of the memory array region 310, the contact region 320, and the gate line slit region 330 are not limited in this disclosure, and the gate line slit region 330 may not enclose the memory array region 310 or the contact region 320 in other embodiments.

The memory array region 310 includes a plurality of channel structures such as channel structures 310(a)-310(h). The contact region 320 (enclosed by the dashed rectangle) is surrounded by the plurality of channel structures and includes a plurality of contact structures such as contact structures 320(a)-320(l). The gate line slit region 330 includes a plurality of gate line slits such as gate line slits 330(a)-330(e).

FIGS. 3B-3D illustrate vertical cross-sectional views of the vertical memory device 300 along dashed line AA′, BB′, and CC′, respectively. It is noted that both FIGS. 3B and 3C are in the Y-Z plane, while FIG. 3D is in the X-Z plane.

Specifically, FIG. 3B illustrates the vertical cross-sectional views of the gate line slits 330(a)-330(c) and the channel structures 310(a)-310(f) along the dashed line AA′ in the Y-X plane. In FIG. 3B, a stack of gate layers 340(a)-340(l) and insulating layers 360(a)-360(l) is formed in the memory array region 310 and over a substrate 370 of the vertical memory device 300. It can be seen that the gate line slits 330(a)-330(c) and the channel structures 310(a)-310(f) are disposed through the stack of gate layers 340(a)-340(l) and insulating layers 360(a)-360(l).

FIG. 3C illustrates the vertical cross-sectional views of the gate line slits 330(d)-330(e), the channel structures 310(g)-310(h), and the contact structures 320(a)-320(b) along the dashed line BB′ in the Y-Z plane. In FIG. 3C, a stack of sacrificial layers 350(a)-350(l) and insulating layers 360(a)-360(l) is formed in the contact region 320 and over the substrate 370 of the vertical memory device 300. In the contact region 320, the contact structures 320(a) and 320(b) are disposed to connect the gate layers 340(a) and 340(h), respectively. Accordingly, the gate layers 340(a) and 340(h) can be extended to replace the portions of the sacrificial layers 350(a) and 350(h) under the contact structures 320(a) and 320(b), respectively. It is also noted that other sacrificial layers, such as 350(b), 350(k), and 350(l), of which the corresponding gate layers 340 (a), 340(k), and 340(l) are not disposed to connect to the contact structure 320(a) or 320(b), can be kept in the vertical memory device 300.

FIG. 3D illustrates the vertical cross-sectional views of the contact structures 320(b), 320(d), 320(f), 320(h), 320(j), and 320(l). From FIG. 3D, it can be seen that, by using the merge formation process, each contact structure can be disposed to connect one of the gate layers without forming a stair-step shape over the contact region 320. For example, the contact structures 320(d) and 320(l) are disposed to connect the gate layers 340(d) and 340(l), respectively.

In the merge formation process, the gate layers 340(a)-340(l) in the vertical memory device 300 can be formed through the gate line slit region 330. For example, the sacrificial layers 350(a)-350(l) can be first formed and then replaced with the gate layers 340(a)-340(l) through the gate line slit region 330. For example, in FIG. 3B, the gate line slits 330(a)-330(c) can be used to form a first portion of the gate layers 340(a)-340(l) that surrounds the channel structures 310(a)-310(f). In FIG. 3C, the gate line slits 330(d)-330(e) can be used to form a second portion of the gate layers 340(a)-340(l) that surrounds the channel structures 310(g)-310(h) and connects to the contact structures 320(a)-320(b).

It is noted that, during the replacement of the sacrificial layers 350, the sacrificial layers 350 are not necessary to be completely removed and at least a part of the sacrificial layers 350 can still be left in the vertical memory device 300, even after all the gate layers 350 have been formed. For example, in FIG. 3C, at least a part of the sacrificial layers 350(a)-350(l) in the contact region 320 can still exist in the vertical memory device 300.

Detailed descriptions of the merge formation process will be described as follows. It is assumed that, before the merge formation process is applied, the stack of alternating sacrificial layers 350(a)-350(l) and insulating layers 360(a)-360(l) has been formed in the memory array region 310, the contact region 320, and the gate line slit region 330. In addition, the channel structures (e.g., 310(a)-310(g)) in the memory array region 310 have also been formed. During the merge formation process, a plurality of photomasks can be used to form contact holes corresponding to the contact structures (e.g., 320(a)-320(l)) in the contact region 320 and form gate line trenches corresponding to the gate line slits (e.g., 330(a)-330(e)) in the gate line slit region 330, respectively. It is noted that regions corresponding to all the channel structures (e.g., 310(a)-310(h)) in the memory array region 310 are not etched during the merge formation process.

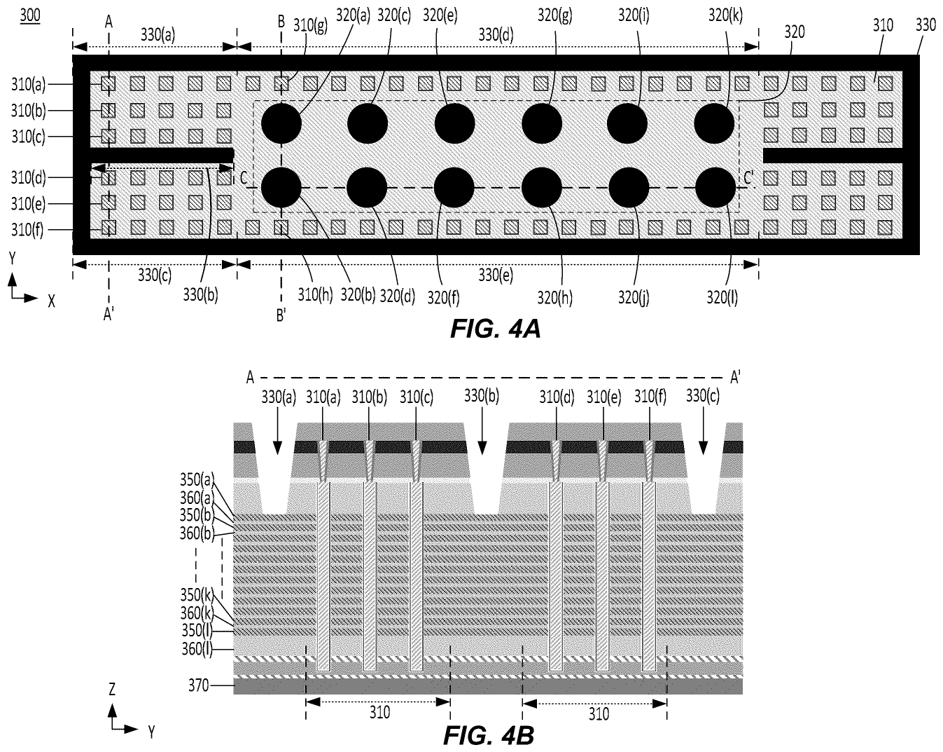

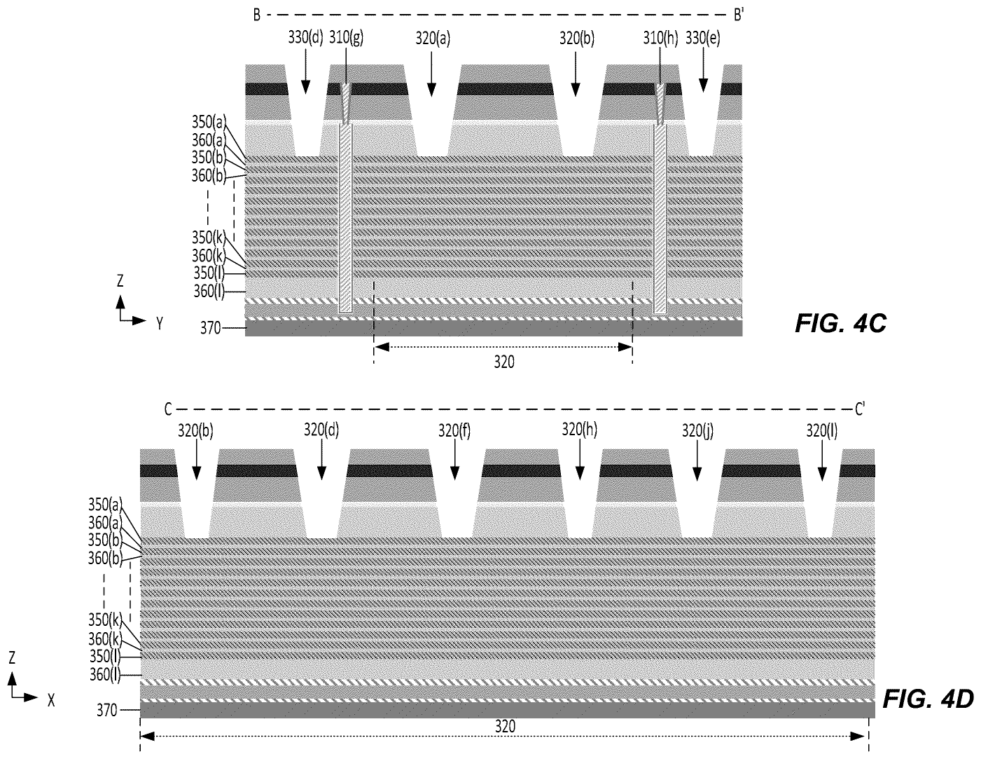

FIGS. 4A-4D illustrate a first contact hole etching step of the merge formation process according to certain embodiments of the disclosure. By using the first contact hole etching step, a first contact hole corresponding to the contact structure 320(a) can be formed.

It is noted that, as shown in FIG. 3C, the contact structure 320(a) connects to the gate layer 340(a), which is formed by replacing the sacrificial layer 350(a). Accordingly, the first contact hole etching step, including the etching of the first contact hole corresponding to the contact structure 320(a), stops at the sacrificial layer 350(a).

Specifically, FIG. 4A illustrates etched regions (black shaded) and unetched regions (gray shaded) of the device 300 in the X-Y plane during the first contact hole etching step. The etched regions correspond to all the contact structures in the contact region 320 and all the gate line slits in the gate line slit region 330, while the unetched regions include the memory region 310. Accordingly, during the first contact hole etching step, the contact holes corresponding to all the contact structures in the contact region 320 and the gate line trenches corresponding to all the gate line slits in the gate line slit region 330 can be etched to the same sacrificial layer 350(a).

FIGS. 4B-4D illustrate vertical cross-sectional views of the device 300 after the first contact hole etching step along the dashed lines AA′ (in the Y-Z plane), BB′ (in the Y-Z plane), and CC′ (in the X-Z plane), respectively. It can be seen that, by using the first contact hole etching step, all layers above the sacrificial layer 350(a) in the contact holes corresponding to all the contact structures in the contact region 320 are removed, and all layers above the sacrificial layer 350(a) in the gate line trenches corresponding to all the gate line slits in the gate line slit region 330 are also removed. Accordingly, the first contact hole corresponding to the contact structure 320(a) is formed by using the first contact hole etching step. After the first contact hole etching step, the first contact hole corresponding to the contact structure 320(a) is not to be etched.

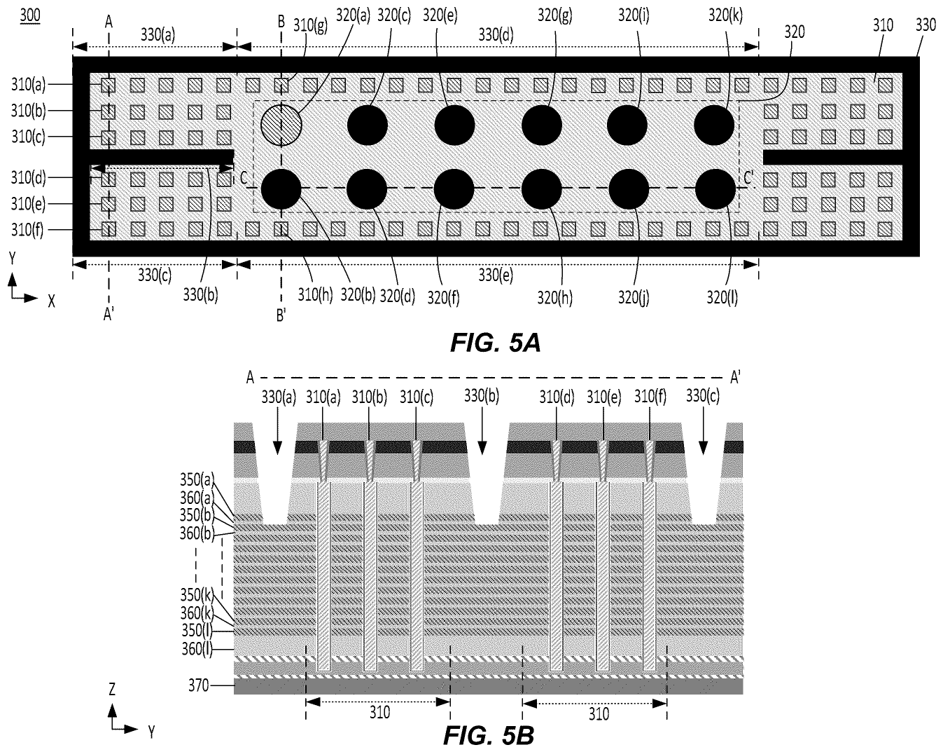

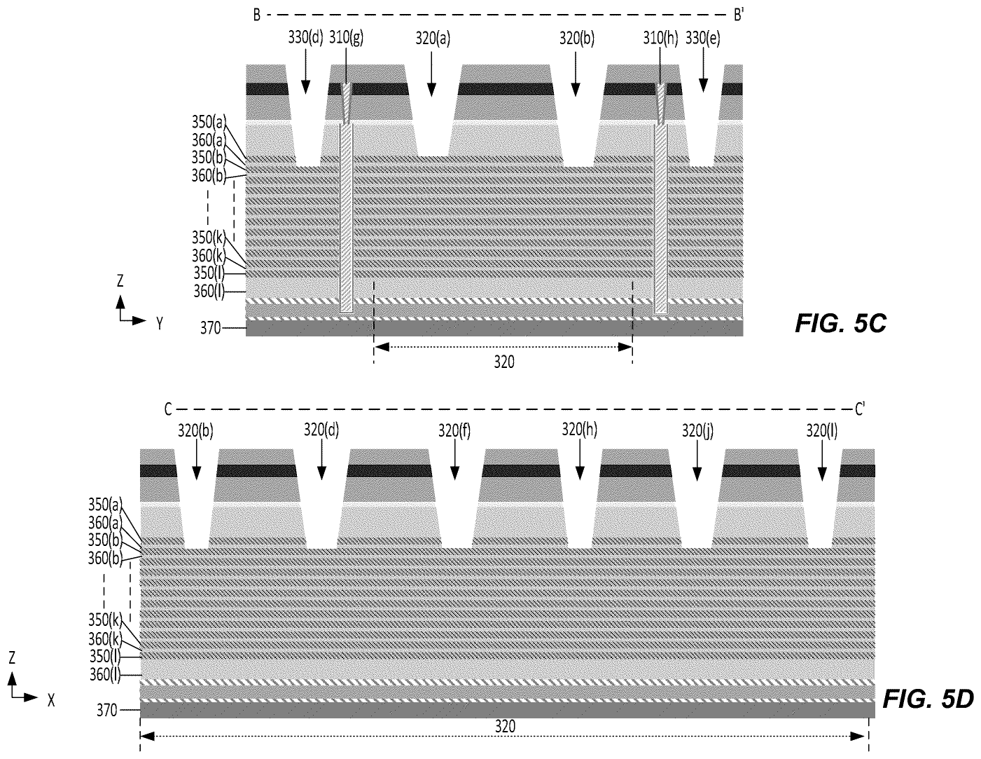

FIGS. 5A-5D illustrate a second contact hole etching step of the merge formation process according to certain embodiments of the disclosure. By using the second contact hole etching step, a second contact hole corresponding to the contact structure 320(d) can be formed.

It is noted that, as shown in FIG. 3D, the contact structure 320(d) connects to the gate layer 340(b), which is formed by replacing the sacrificial layer 350(b). Accordingly, the second contact hole etching step, including the etching of the second contact hole corresponding to the contact structure 320(d), stops at the sacrificial layer 350(b).

Specifically, FIG. 5A illustrates etched regions (black shaded) and unetched regions (gray shaded) of the device 300 in the X-Y plane during the second contact hole etching step. As discussed above, the first contact hole corresponding to the contact structure 320(a) is not to be etched after the first contact hole etching step. Thus, the unetched regions include the region corresponding to the contact structure 320(a), and the etched regions correspond to all other contact structures (320(b)-320(l)) in the contact region 320 and all the gate line slits in the gate line slit region 330. Accordingly, during the second contact hole etching step, the first contact hole corresponding to the contact structure 320(a) is not etched; and the contact holes corresponding to all other contact structures (320(b)-320(l)) in the contact region 320 and the gate line trenches corresponding to all the gate line slits in the gate line slit region 330 are etched to the same sacrificial layer 350(b).

FIGS. 5B-5D illustrate vertical cross-sectional views of the device 300 after the second contact hole etching step along the dashed lines AA′ (in the Y-Z plane), BB′ (in the Y-Z plane), and CC′ (in the X-Z plane), respectively. It can be seen that, by using the second contact hole etching step, the sacrificial layer 350(a) and the insulating layer 360(a) in the contact holes corresponding to all the contact structures except the contact structure 320(a) in the contact region 320 are removed; the sacrificial layer 350(a) and the insulating layer 360(a) in the gate line trenches corresponding to all the gate line slits in the gate line slit region 330 are also removed; and the contact hole corresponding to the contact structure 320(a) is not further etched and kept as same as that in FIG. 4C. Accordingly, the second contact hole corresponding to the contact structure 320(d) is formed by using the second contact hole etching step. After the second contact hole etching step, the second contact hole corresponding to the contact structure 320(d) is not to be etched.

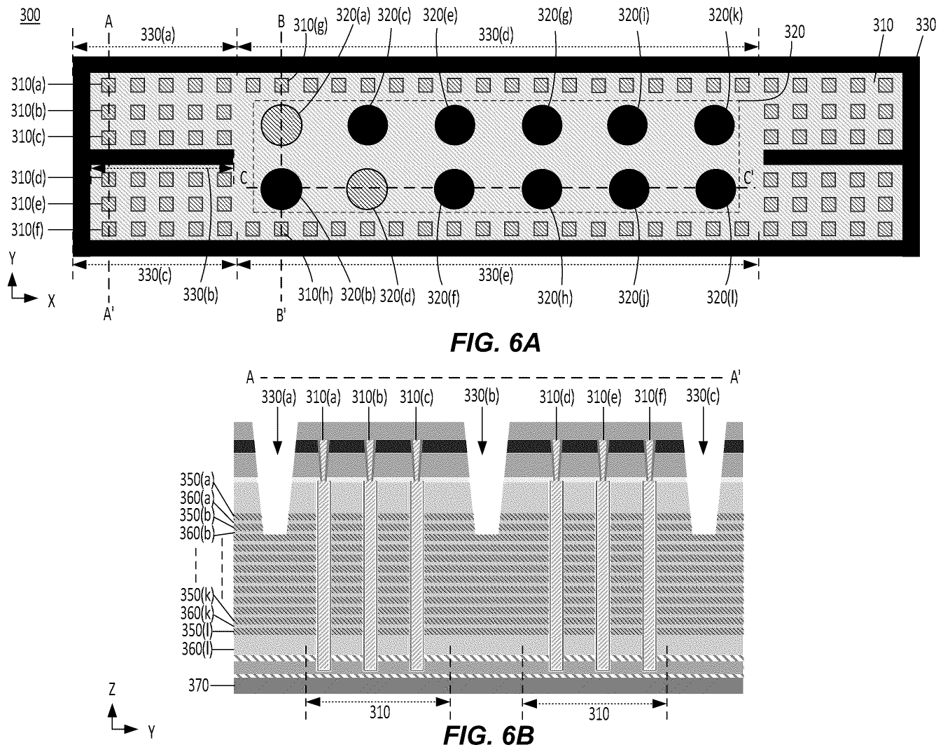

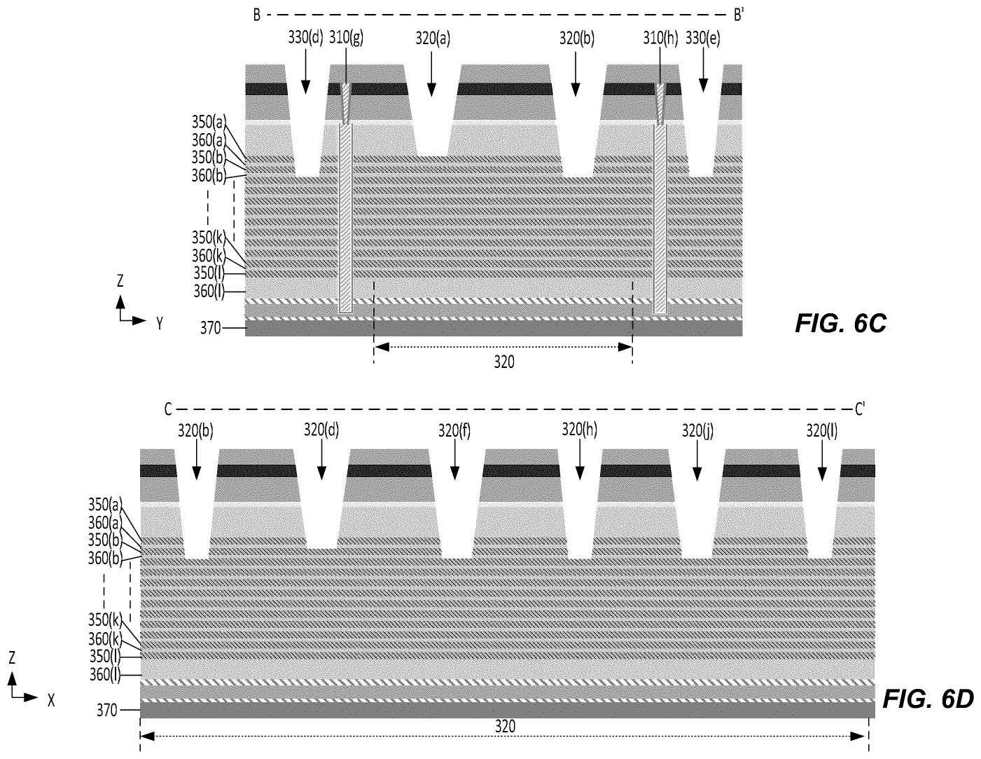

FIGS. 6A-6D illustrate a third contact hole etching step of the merge formation process according to certain embodiments of the disclosure. By using the third contact hole etching step, a third contact hole corresponding to the contact structure 320(j) can be formed.

It is noted that, as shown in FIG. 3D, the contact structure 320(j) connects to the gate layer 340(c), which is formed by replacing the sacrificial layer 350(c). Accordingly, the third contact hole etching step, including the etching of the third contact hole corresponding to the contact structure 320(j), stops at the sacrificial layer 350(c).

Specifically, FIG. 6A illustrates etched regions (black shaded) and unetched regions (gray shaded) of the device 300 in the X-Y plane during the third contact hole etching step. As discussed above, the contact hole corresponding to the contact structure 320(d) is not to be etched after the second contact hole etching step. Thus, the unetched regions include the regions corresponding to the contact structures 320(a) and 320(d), and the etched regions correspond to all other contact structures 320(b)-320(c) and 320(e)-320(l) in the contact region 320 and all the gate line slits in the gate line slit region 330. Accordingly, during the third contact hole etching step, the contact holes corresponding to the contact structures 320(a) and 320(d) are not etched, and the contact holes corresponding to all other contact structures 320(b)-320(c) and 320(e)-320(l) in the contact region 320 and the gate line trenches corresponding to all the gate line slits in the gate line slit region 330 are etched to the same sacrificial layer 350(c).

FIGS. 6B-6D illustrate vertical cross-sectional views of the device 300 after the third contact hole etching step along the dashed lines AA′ (in the Y-Z plane), BB′ (in the Y-Z plane), and CC′ (in the X-Z plane), respectively. It can be seen that, by using the third contact hole etching step, the sacrificial layer 350(b) and the insulating layer 360(b) in the contact holes corresponding to the contact structures 320(b)-320(c) and 320(e)-320(l) in the contact region 320 are removed, the sacrificial layer 350(b) and the insulating layer 360(b) in the gate line trenches corresponding to all the gate line slits in the gate line slit region 330 are also removed; and the contact holes corresponding to the contact structures 320(a) and 320(d) are not further etched and kept as same as those shown in FIGS. 5C-5D. Accordingly, the third contact hole corresponding to the contact structure 320(j) is formed by using the third contact hole etching step. After the third contact hole etching step, the third contact hole corresponding to the contact structure 320(j) is not to be etched.

According to aspects of the disclosure, the etching of the contact structures 320(b)-320(c), 320(e)-320(i), and 320(k)-320(l) can be implemented using similar contact hole etching steps with different photomasks. In addition, all the gate line slits in the gate line slit region 330 are etched in each contact hole etching step until all the contact structures 320(a)-320(l) are completed etched.

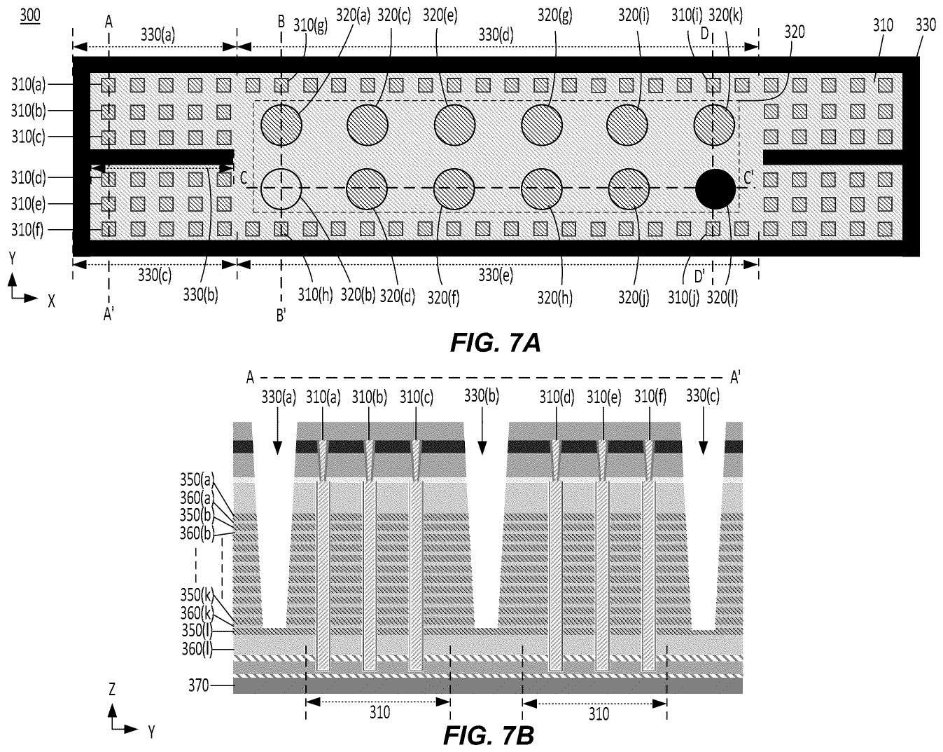

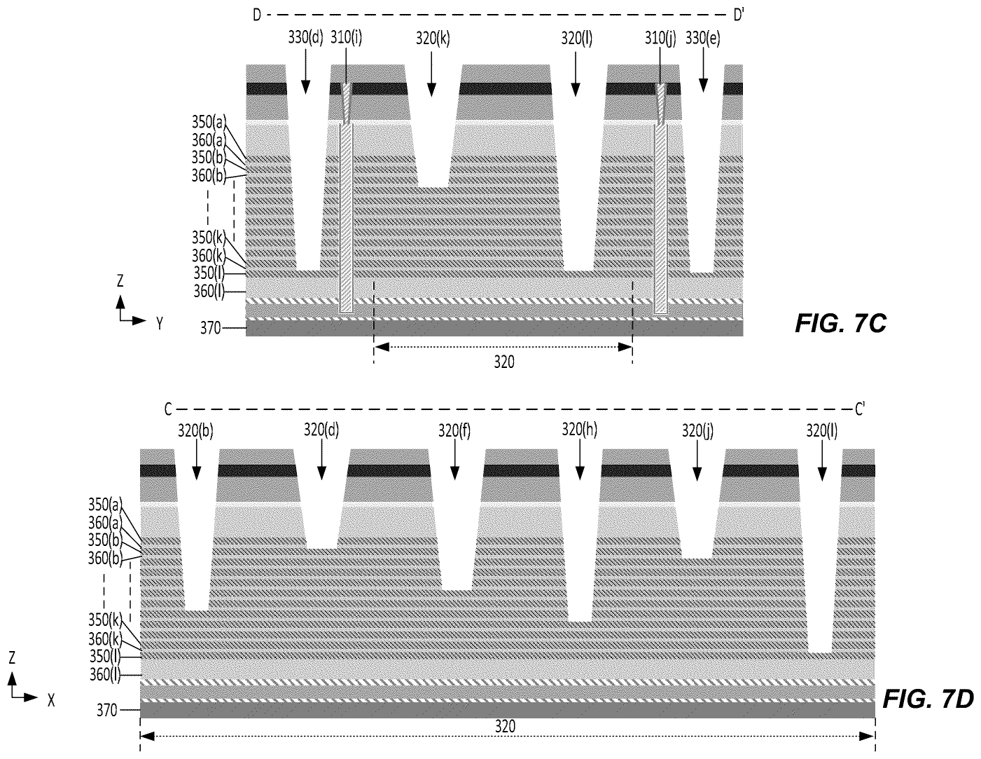

FIGS. 7A-7D illustrate a last contact hole etching step of the merge formation process according to certain embodiments of the disclosure. By using the last contact hole etching step, a last contact hole corresponding to the contact structure 320(l) can be formed. It is noted that there are other contact hole etching steps between the third step and the last step to etch the contact structures 320(b)-320(c), 320(e)-320(i), and 320(k). In addition, all the gate line slits in the gate line slit region 330 are also etched during these contact hole etching steps.

It is noted that, as shown in FIG. 3D, the contact structure 320(l) connects to the gate layer 340(l), which is formed by replacing the sacrificial layer 350(l). Accordingly, the last contact hole etching step, including the etching of the last contact hole corresponding to the contact structure 320(l), stops at the sacrificial layer 350(l).

Specifically, FIG. 7A illustrates etched regions (black shaded) and unetched regions (gray shaded) of the device 300 in the X-Y plane during the last contact hole etching step. Since the contact structures 320(a)-320(k) have been completed etched, the unetched regions include the regions corresponding to the contact structures 320(a)-320(k). The etched regions correspond to the contact structure 320(l) in the contact region 320 and all the gate line slits in the gate line slit region 330. Accordingly, during the last contact hole etching step, the contact holes corresponding to the contact structures 320(a)-320(k) are not etched, and the last contact hole corresponding to the contact structure 320(l) and the gate line trenches corresponding to all the gate line slits in the gate line slit region 330 are etched to the same sacrificial layer 350(l).

FIGS. 7B-7D illustrate vertical cross-sectional views of the device 300 after the last contact hole etching step along the dashed lines AA′ (in the Y-Z plane), DD′ (in the Y-Z plane), and CC′ (in the X-Z plane), respectively. It can be seen that, by using the last contact hole etching step, the sacrificial layer 350(k) and the insulating layer 360(k) in the last contact hole corresponding to the contact structure 320(l) in the contact region 320 are removed; the sacrificial layer 350(k) and the insulating layer 360(k) in the gate line trenches corresponding to all the gate line slits in the gate line slit region 330 are also removed; and the contact holes corresponding to the contact structures 320(a)-320(k) are not further etched and kept as same as those in a contact hole etching step previous to the last contact hole etching step. Accordingly, the last contact hole corresponding to the contact structure 320(j) is formed by using the last contact hole etching step.

It can also be seen that, in FIG. 7D, the contact holes corresponding to the contact structures 320(b), 320(d), 320(f), 320(h), 320(j), and 320(l) have different depths, so that the contact structures 320(b)-320(l) can be formed on different sacrificial layers 350(b), 350(d), 350(f), 350(h), 350(j), and 350(l), respectively.

In addition, during the above contact hole etching steps, all the gate line slits in the gate line slit region 330 are etched. Accordingly, when the etching of all the contact structures 320(a)-320(l) in the contact region 320 is completed, the etching of all the gate line slits in the gate line slit region 330 is also completed.

After all the contact structures 320(a)-320(l) in the contact region 320 and all the gate line slits in the gate line slit region 330 are completely etched, a sacrificial material such as poly silicon can be filled into the contact holes corresponding to all the contact structures in the contact region 320 and into the gate line trenches corresponding to all the gate line slits in the gate line slit region 330. This step can be referred to as a sacrificial material filling step. It is noted that the sacrificial material is not limited to ploy silicon, and can be any suitable material.

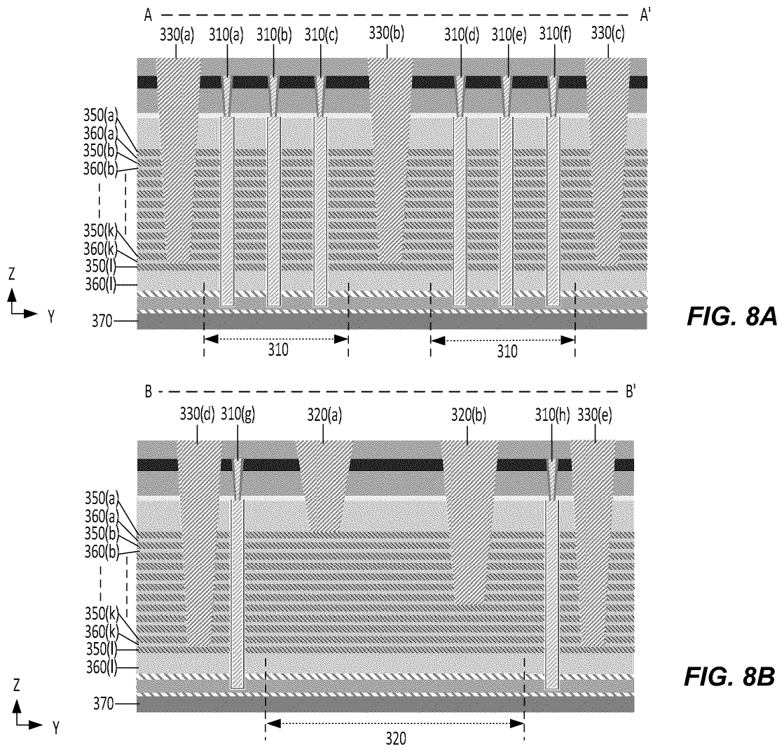

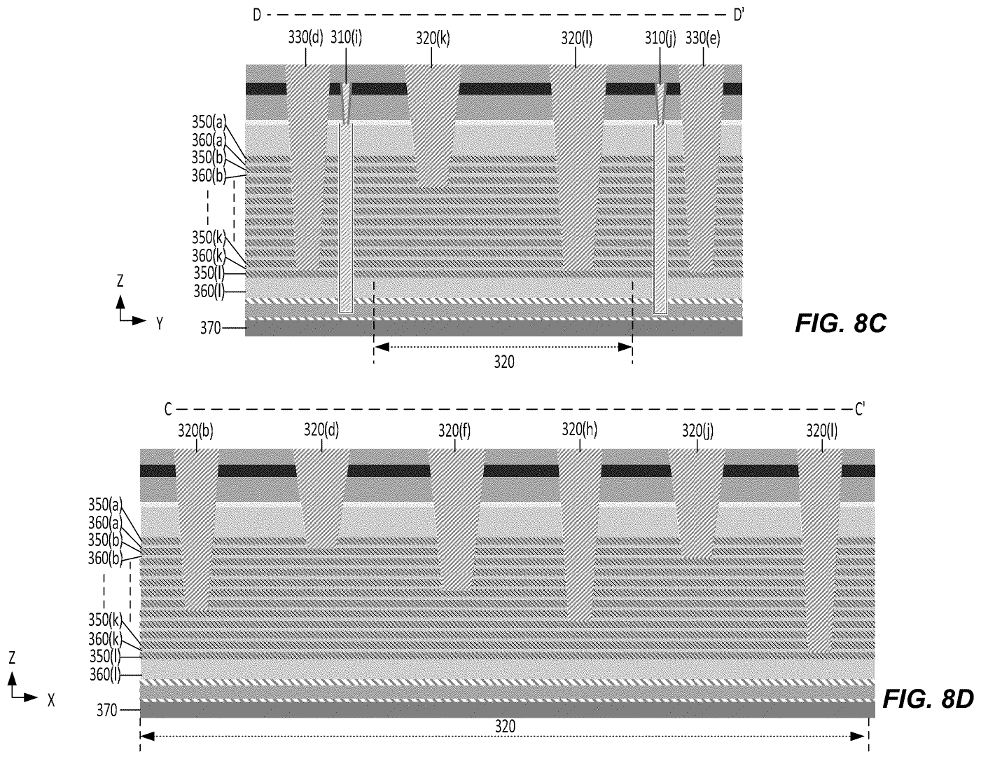

FIGS. 8A-8D illustrate vertical cross-sectional views of the device 300 after the sacrificial material filling step of the merge formation process along the dashed lines AA′ (in the Y-Z plane), BB′ (in the Y-Z plane), DD′ (in the Y-Z plane), and CC′ (in the X-Z plane), respectively. It can be seen that the contact holes corresponding to all the contact structures in the contact region 320 and the gate line trenches corresponding to all the gate line slits in the gate line slit region 330 are filled with the sacrificial material.

After the sacrificial material filling step is completed, the contact holes corresponding to all the contact structures in the contact region 320 are opened, and a metal material such as tungsten. This step can be referred to as a contact structure forming step.

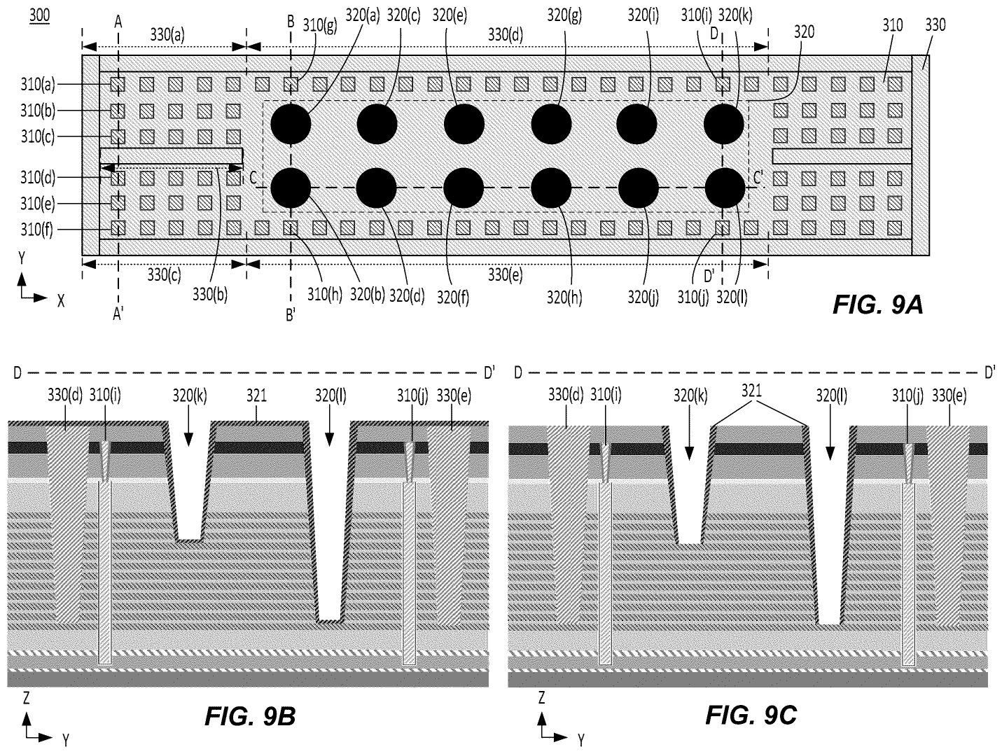

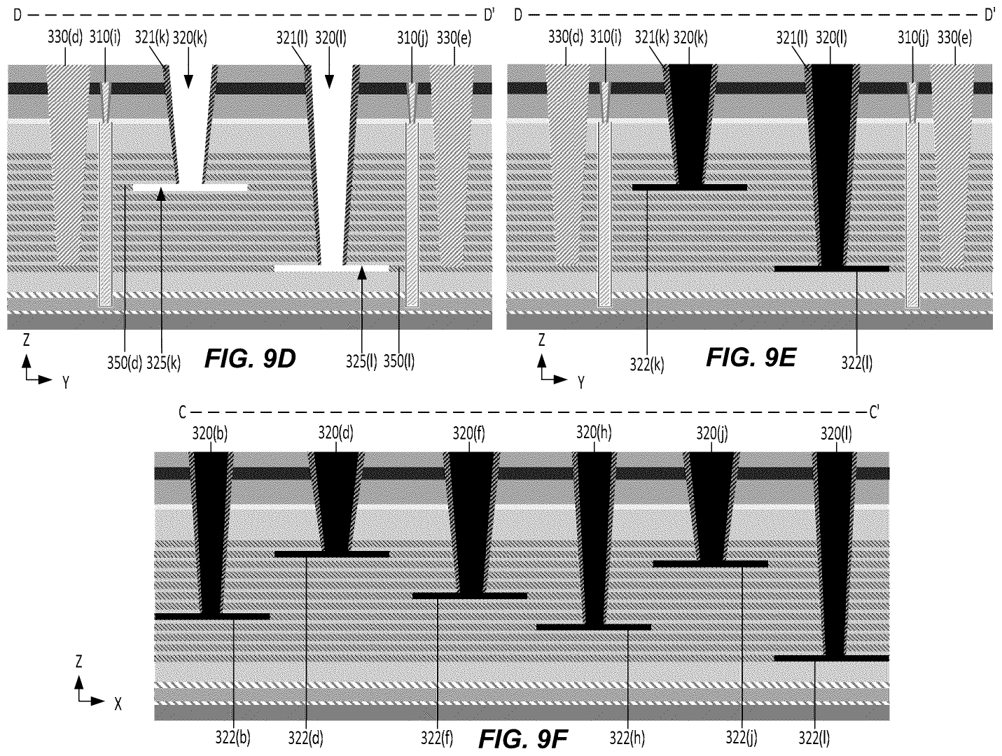

FIGS. 9A-9F illustrate the contact structure forming step of the merge formation process according to certain embodiments of the disclosure.

Specifically, FIG. 9A illustrates etched regions (black shaded) and unetched regions (gray shaded) of the device 300 in the X-Y plane during the contact structure forming step. As shown in FIG. 9A, the etched regions correspond to all the contact structures in the contact region 320.

FIGS. 9B-9E illustrate vertical cross-sectional views of the device 300 during the contact structure forming step of the merge formation process along the dashed line DD′ (in the Y-Z plane).

First, the sacrificial material (e.g., poly silicon) inside the contact holes corresponding to all the contact structures in the contact region 320 is removed, and a spacer layer 321, such as silicon oxide, is formed on a sidewall and a bottom of each of the contact holes. For example, as shown in FIG. 9B, the sacrificial material in the contact holes corresponding to the contact structures 320(k) and 320(l) is removed, and the spacer layer 321 is formed on a sidewall and a bottom of each contact structure 320(k) or 320(l).

Second, the spacer layer 321 on the bottom of each of the contact holes is removed. For example, as shown in FIG. 9C, the spacer layer 321 on the bottoms of the contact structures 320(k) and 320(l) is removed.

Third, a portion of one of the sacrificial layers underneath and adjacent to the bottom of each of the contact structure is removed, and an open space 325 is formed for each of the contact structure. For example, as shown in FIG. 9D, a portion of the sacrificial layer 350(d) and a portion of the sacrificial layer 350(j) are removed, respectively. Accordingly, the open spaces 325(k) and 325(l) are formed.

Fourth, the metal material is filled into the open spaces 325 and the contact holes to form the contact structures 320, in which the filling of the metal material into the open spaces 325 forms conductive pads 322 of the contact structures in the contact region 320. For example, as shown in FIG. 9E, the metal material is filled into the open spaces 325(k) and 325(l) and the contact holes to form the contact structures 320(k) and 320(l), in which the filling of the metal material into the open spaces 325(k) and 325(l) forms the conductive pads 322(k) and 322(l) of the contact structure 320(k) and 320(l), respectively.

FIG. 9F shows vertical cross-sectional views of the device 300 after the contact structure forming step along the dashed line CC′ (in the X-Z plane). It can be seen that the metal material is filled into the contact holes and the open spaces resulted from the removed portions of the sacrificial layers underneath the contact holes to form the contact structures 320(b), 320(d), 320(f), 320(h), 320(j), and 320(l). The filling of the metal material into the open spaces form the conductive pads 322(b), 322(d), 322(f), 322(h), 322(j), and 322(l) of the contact structures 320(b), 320(d), 320(f), 320(h), 320(j), and 320(l), respectively.

After the contact structures are formed, the gate line trenches near to the contact region 320 can be opened and the sacrificial layers 350 around the gate line trenches can be replaced with a first portion of the gate layers 340 so that the contact structures in the contact region 320 can be connected to the first portion of the gate layers 340. This step can be referred to as a contact structure connecting step.

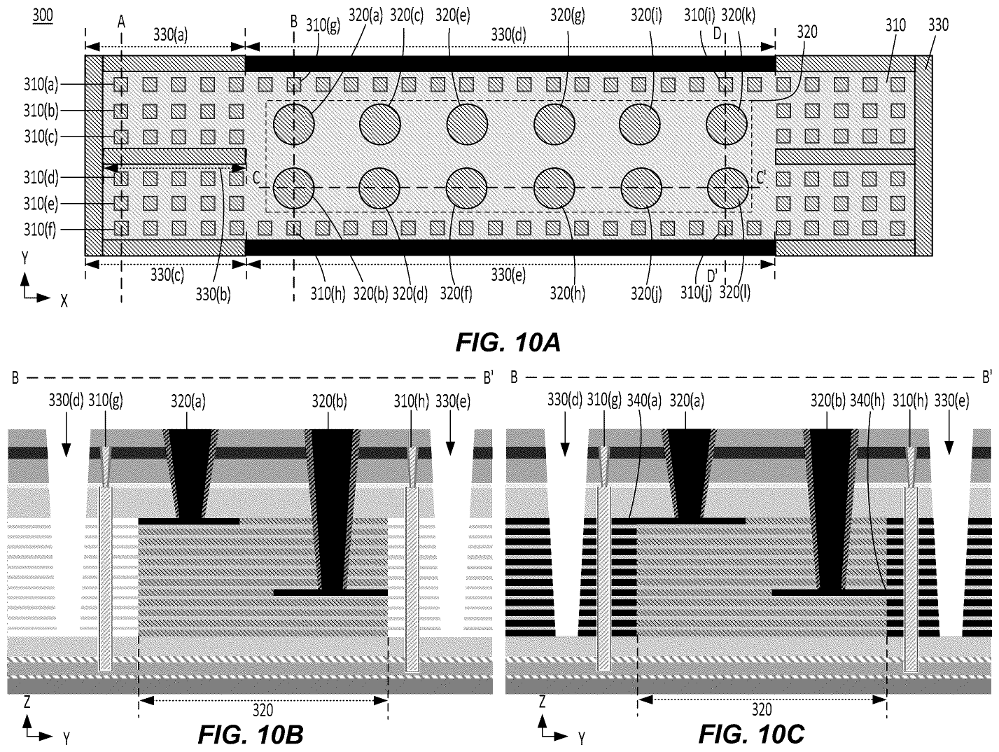

FIGS. 10A-10C illustrate the contact structure connecting step of the merge formation process according to certain embodiments of the disclosure. By using the contact structure connecting step, the sacrificial layers 350 around the gate line trenches near to the contact region 320 are replaced with the firs portion of the gate layers 340 so that the contact structures in the contact region 320 can be connected to the first portion of the gate layers 340.

Specifically, FIG. 10A illustrates etched regions (black shaded) and unetched regions (gray shaded) of the device 300 in the X-Y plane during the contact structure connecting step. The etched regions correspond to the gate line slits near to the contact region 320, such as the gate line slits 330(d) and 330(e).

FIGS. 10B-10C illustrate vertical cross-sectional views of the device 300 during the contact structure connecting step of the merge formation process along the dashed line BB′ (in the Y-Z plane). First, as shown in FIG. 10B, the sacrificial material in the gate line trenches corresponding to the gate line slits 330(d) and 330(e) is removed, and the sacrificial layers 350 around the gate line trenches are also removed. Then, the metal material is filled into the open spaces resulted from the removed sacrificial layers to form the first portion of the gate layers 340 connecting to the contact structures in the contact region 320. For example, as shown in FIG. 10C, the newly formed gate layers 340(a) and 340(h) connect to the contact structures 320(a) and 320(b), respectively, as shown in FIG. 10C.

After the first portion of the gate layers 340, which is near to the contact region 320, is formed and connects to the contact structures in the contact region 320, an insulating or dielectric material can be filled into the gate line trenches near to the contact region 320, such as the gate line trenches corresponding to the gate line slits 330(d) and 330(e). In an embodiment, a spacer layer can be formed on a sidewall and a bottom of each of the gate line trenches, and then the insulating or dielectric material can be filled into each of the gate line trenches.

Further, the gate line trenches near to the array region 310 can be opened and the sacrificial layers 350 in the array region 310 can be replaced with a second portion of the gate layers 340. This step can be referred to as a gate layer forming step.

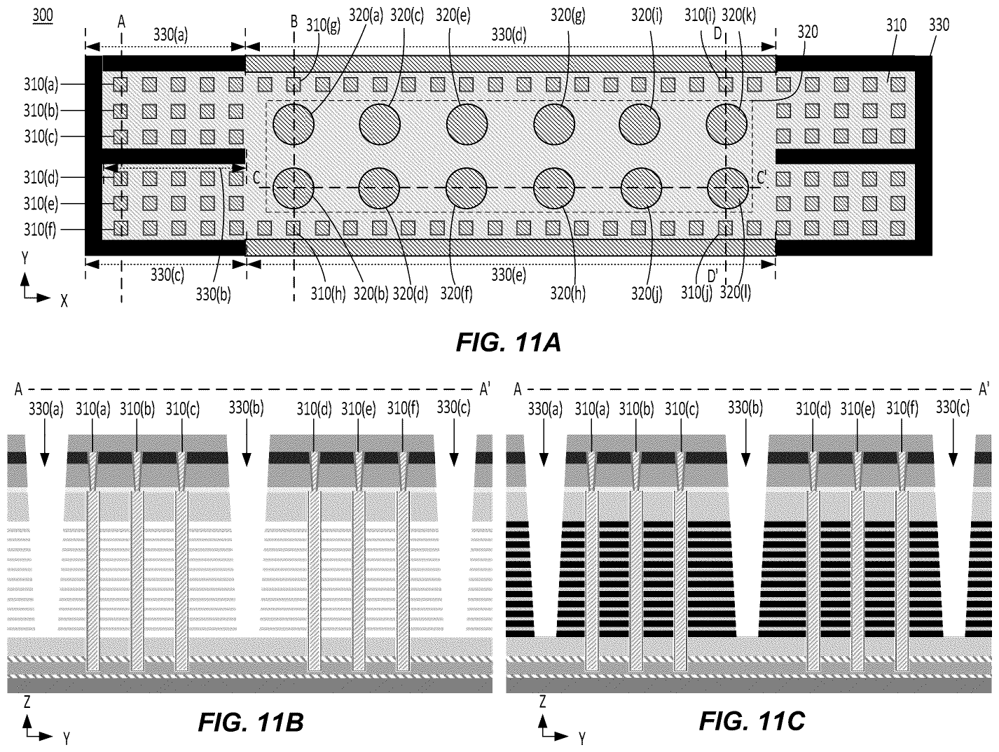

FIGS. 11A-11C illustrate the gate layer forming step of the merge formation process according to certain embodiments of the disclosure. By using the contact structure connecting step, the sacrificial layers 350 in the array region 310 can be replaced with the second portion of the gate layers 340 so that the second portion of the gate layers 340 in the array region 310 can be connected to the first portion of the gate layers 340 formed in the contact structure connecting step.

Specifically, FIG. 11A illustrates etched regions (black shaded) and unetched regions (gray shaded) of the device 300 in the X-Y plane during the gate layer forming step. The etched regions correspond to the gate line slits near to the array region 310, such as the gate line slits 330(a)-330(c).

FIGS. 11B-11C illustrate vertical cross-sectional views of the device 300 during the gate layer forming step of the merge formation process along the dashed line AA′ (in the Y-Z plane). First, the sacrificial material in the gate line trenches corresponding to the gate line slits near to the array region 310 is removed. For example, as shown in FIG. 11B, the sacrificial material in the gate line trenches corresponding to the gate line slits 330(a)-330(c) is removed, and the sacrificial layers in the array region 310 are also removed. Then, through the gate line trenches near to the array region 310, the metal material is filled into the open spaces resulted from the removed sacrificial layers to form the second portion of the gate layers 340 so that the second portion of the gate layers 340 connects to the first portion of the gate layers 340 formed in the contact structure connection step. For example, as shown in FIG. 11C, the gate layers 340(a)-340(l) are formed through the gate line slits 330(a)-330(c).

After the second portion of the gate layers 340, which is in the array region 310, is formed and connects to the first portion of the gate layer 340, which is near to the contact region 320, an insulating or dielectric material can be filled into the gate line trenches near to the array region 310, such as the gate line trenches corresponding to the gate line slits 330(a)-330(c). In an embodiment, a spacer layer can be formed on a sidewall and a bottom of each of the gate line trenches, and then the insulating or dielectric material can be filled into each of the gate line trenches. For example, as shown in FIGS. 3B-3C, each gate line trench includes a respective spacer layer 321 and insulating material 322.

According to aspects of the disclosure, in order to form a gate line slit during a formation of a contact structure in a contact region, a critical dimension of a gate line slit can be increased to a certain level such that a size ratio between a critical dimension of a channel structure and a critical dimension of a gate line slit is equal to or less than a size threshold. In an example, the size threshold can be between 0.5 and 1.5. In an example, the size threshold can be between 0.5 and 0.9. By increasing the critical dimension of the gate line slit close to the critical dimension of the contact structure in the contact region, photolithographic patterns of the gate line slit and the contact structure can be developed and exposed on a same photoresist.

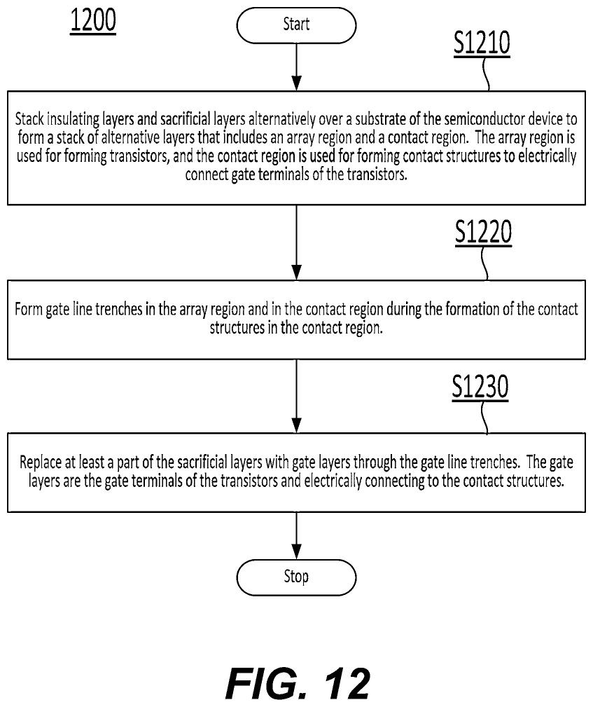

FIG. 12 illustrates a flowchart outlining an exemplary manufacturing process 1200 for fabricating the vertical memory device 300 according to certain embodiments of the disclosure. The manufacturing process 1200 May start from step S1210.

At step S1210, the manufacturing process 1200 stacks insulating layers and sacrificial layers alternatively over a substrate of the semiconductor device to form a stack of alternative layers that includes an array region and a contact region. The array region is used for forming transistors, and the contact region is used for forming contact structures to electrically connect gate terminals of the transistors. Then, the manufacturing process 1200 proceeds to step S1220.

At step S1220, the manufacturing process 1200 forms gate line trenches in the array region and in the contact region during the formation of the contact structures in the contact region. Then, the manufacturing process 1200 proceeds to step S1230.

At step S1230, the manufacturing process 1200 replaces at least a part of the sacrificial layers with gate layers through the gate line trenches. The gate layers are the gate terminals of the transistors and electrically connect to the contact structures. Then, the manufacturing process 1200 terminates.

In an embodiment, for each of the contact structures in the contact region, the manufacturing process 1200 forms a contact hole through a subset of the stack of alternative layers in the contact region. A bottom of the contact hole is one of the sacrificial layers. Then, the manufacturing process 1200 forms a first spacer layer on a sidewall and the bottom of the contact hole. Further, the manufacturing process 1200 removes the first spacer layer on the bottom of the contact hole, and removes a portion of the one of the sacrificial layers to form a first open space in the one of the sacrificial layers. Furthermore, the manufacturing process 1200 fills a conductive material into the first open space resulted from the removed portion of the one of the sacrificial layers to form a conductive pad of the respective contact structure, and fills the conductive material into the contact hole to form the respective contact structure.

In an embodiment, the manufacturing process 1200 keeps the first spacer layer on the sidewall of the contact hole during the removing of the first spacer layer on the bottom of the contact hole.

In an embodiment, the first spacer layer includes silicon oxide and the conductive material includes tungsten.

In an embodiment, the manufacturing process 1200 forms the gate line trenches in the array region and in the contact region during the formation of the contact holes. The gate line trenches and the contact holes are formed under a same etching process. The etching process includes multiple steps to form the contact holes with different depths. The multiple steps are also used to form the gate line trenches. In the etching process, a same number of etching steps is used in the formation of a contact hole with a maximum depth among the contact holes and the formation of the gate line trenches.

In an embodiment, before the first spacer layer is formed, the manufacturing process 1200 fills the gate line trenches and the contact holes with a sacrificial material, and removes the sacrificial material inside the contact holes in the contact region.

In an embodiment, the sacrificial material includes poly silicon.

In an embodiment, the manufacturing process 1200 removes the sacrificial material inside the gate line trenches in the contact region. The manufacturing process 1200 further removes the sacrificial layers adjacent to the gate line trenches in the contact region through the gate line trenches in the contact region, until all the conductive pads of the contact structures are open for connecting the gate layers. Then, the manufacturing process 1200 fills the conductive material into second open spaces resulted from the removed sacrificial layers to form a first portion of the gate layers so that the first portion of the gate layers electrically connects to the conductive pads of the contact structures.

In an embodiment, the manufacturing process 1200 keeps at least a portion of the sacrificial layers underneath the conductive pads of the contact structures during the removing of the sacrificial layers adjacent to the gate line trenches in the contact region.

In an embodiment, the manufacturing process 1200 removes the sacrificial material inside the gate line trenches in the array region, and then removes the sacrificial layers in the array region through the gate line trenches in the array region. Further, the manufacturing process 1200 fills the conductive material into third open spaces resulted from the removed sacrificial layers in the array region to form a second portion of the gate layers so that the second portion of the gate layers electrically connects to the first portion of the gate layers.

In an embodiment, the manufacturing process 1200 fills the gate line trenches in the array region and in the contact region with one or more dielectric materials.

In an embodiment, for each gate line trench, the manufacturing process 1200 forms a second spacer layer on a sidewall and a bottom of the respective gate line trench, and then fills a dielectric material into the respective gate line trench.

In an embodiment, a ratio between a critical dimension of each of the contact structures and a critical dimension of each of the gate line trenches is less than or equal to a threshold. For example, the threshold is between 0.5 and 1.5.

The present disclosure provides a semiconductor device (e.g., the vertical memory device 300). The semiconductor includes a substrate and a stack of alternative layers including insulating layers and gate layers that are stacked alternatively over the substrate. The stack of alternative layers includes an array region and a contact region. The semiconductor device further includes a plurality of channel structures disposed through the stack of alternative layers in the array region. Each channel structure forms a stack of transistors in a series configuration with the gate layers being gate terminals of the stack of transistors. The semiconductor includes a plurality of contact structures disposed in the contact region. Each contact structure electrically connects to one of the gate layers. The semiconductor includes a plurality of gate line trenches disposed through the stack of alternative layers in the array region and in the contact region. The plurality of gate line trenches are formed during the formation of the plurality of contact structures in the contact region.

In an embodiment, the semiconductor device further includes one or more sacrificial layers underneath the plurality of contact structures.

In an embodiment, each of the plurality of contact structures includes a first spacer layer on a sidewall of the respective contact structure.

In an embodiment, each of the plurality of gate line trenches includes a second spacer layer on a sidewall of the respective gate line trench.

In an embodiment, a ratio between a critical dimension of each of the plurality of contact structures and a critical dimension of each of the plurality of gate line trenches is less than or equal to a threshold. For example, the threshold is between 0.5 and 1.5.

It is noted that the exemplary semiconductor devices in this disclosure can be any suitable device, for example, memory circuits, a semiconductor chip (or die) with memory circuits formed on the semiconductor chip, a semiconductor wafer with multiple semiconductor dies formed on the semiconductor wafer, a stack of semiconductor chips, a semiconductor package that includes one or more semiconductor chips assembled on a package substrate, and the like. The substrates of the exemplary semiconductor devices can be any suitable substrate, such as a silicon (Si) substrate, a germanium (Ge) substrate, a silicon-germanium (SiGe) substrate, and/or a silicon-on-insulator (SOI) substrate. These substrates may include one or more semiconductor materials, for example, a Group IV semiconductor, a Group III-V compound semiconductor, and/or a Group II-VI oxide semiconductor. The Group IV semiconductor may include Si, Ge, or SiGe. These substrates can include a bulk wafer or an epitaxial layer.

In various embodiments, in addition to the 3D NAND memory circuitry, the exemplary semiconductor devices can include other suitable circuitry, such as logic circuitry, power circuitry, and the like that is formed on the substrates, or other suitable substrates, and is suitably coupled with the 3D NAND memory circuitry.

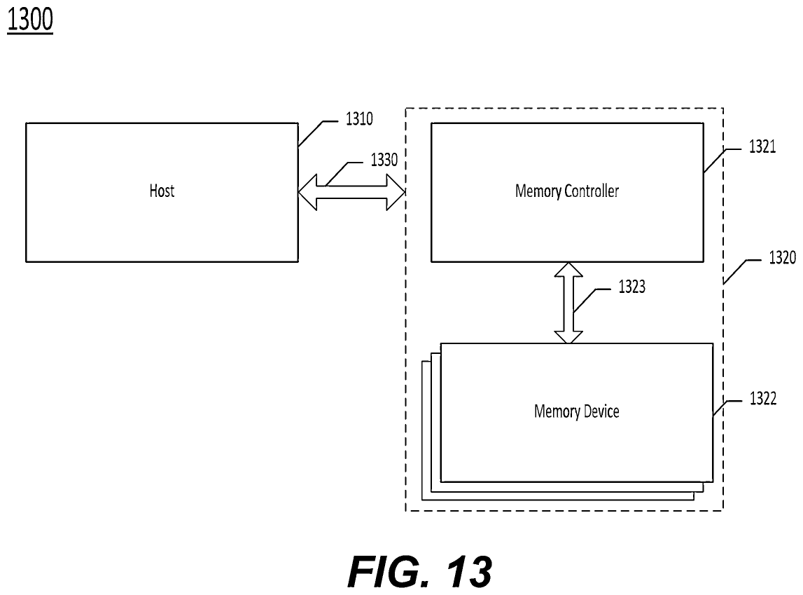

FIG. 13 illustrates an exemplary electronic system 1300 according to certain embodiments of the disclosure. The electronic system 1300 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having memory devices therein.

As shown in FIG. 13, the electronic system 1300 can include a host 1310 and a memory system 1320. The host 1310 can be a processor of an electronic device, such as a central processing unit (CPU), an application processor (AP), a system-on-chip (SoC), or the like. The host 1310 can be configured to send data to and/or receive data from the memory system 1320 through a communication interface 1330.

The memory system 1320 can include a memory controller 1321 and a plurality of memory devices 1322. Each of the plurality of memory devices 1322 can be any memory device disclosed in the present disclosure. The memory controller 1321 can communicate with the plurality of memory devices 1322 through a communication interface 1323. In an example, the memory controller 1321 can be configured to control operations of the plurality of memory devices 1322, such as reading, erasing, and programming operations. The memory controller 1321 can also be configured to manage various functions with respect to data stored or to be stored in the plurality of memory devices 1322, including, but not limited to, bad-block management, garbage collection, logical-to-physical address conversion, wear leveling, and the like. The memory controller 1321 can be configured to process error correction codes (ECCs) with respect to the data read from or programmed/written into the plurality of memory devices 1322. In addition, any other suitable functions can be performed by the memory controller 1321, for example, formatting at least one of the plurality of memory devices 1322.

In various examples, the memory controller 1321 can operate in a secure digital (SD) card, a compact Flash (CF) card, a universal serial bus (USB) Flash drive, a solid state drive (SSD), an embedded multi-media-cards (eMMCs), and the like. The memory controller 1321 and the plurality of the memory devices 1322 can be integrated into various types of storage devices.

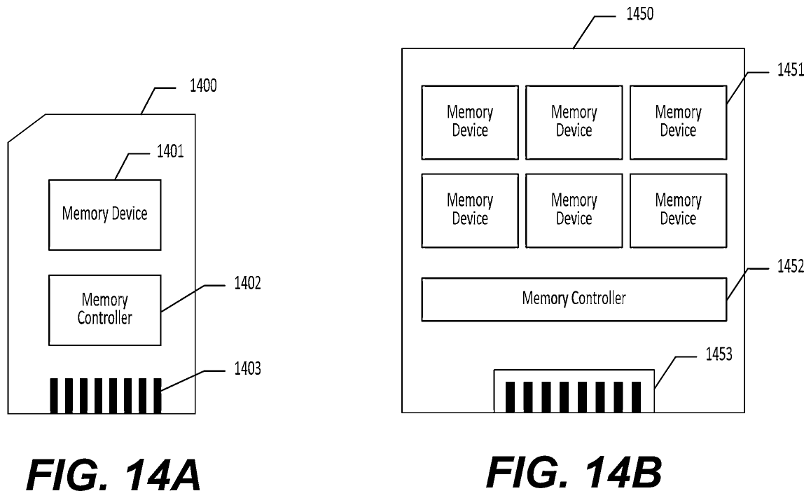

FIG. 14A shows an exemplary memory card 1400 according to certain embodiments of the disclosure. The memory card 1400 can include a memory device 1401, a memory controller 1402, and a memory card connector 1403. The memory card 1400 can include a PC card (PCMCIA, Personal Computer Memory Card International Association), a CF card, a smart media (SM) card, a memory stick, a multimedia card (MMC, RS-MMC, MMCmicro), an SD card (SD, miniSD, microSD, SDHC), UFS, and the like. The memory card connector 1403 can couple the memory card 1400 to a host (e.g., the host 1310 in FIG. 13).

FIG. 14B shows an exemplary SSD 1450 according to certain embodiments of the disclosure. The SSD 1450 can include a plurality of memory devices 1451, a memory controller 1452, and an SSD connector 1453. The SSD connector 1453 can couple the SSD 1450 to a host (e.g., the host 1310 in FIG. 13).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
stacking insulating layers and sacrificial layers alternatively over a substrate of the semiconductor device to form a stack of alternative layers that includes an array region and a contact region, the array region being used for forming transistors, and the contact region being used for forming contact structures to electrically connect gate terminals of the transistors;
forming gate line trenches in the array region and in the contact region during the formation of the contact structures in the contact region; and
replacing at least a part of the sacrificial layers with gate layers through the gate line trenches, the gate layers being the gate terminals of the transistors and electrically connecting to the contact structures.

2. The method of claim 1, wherein the formation of the contact structures includes:
for each of the contact structures in the contact region,
forming a contact hole through a subset of the stack of alternative layers in the contact region, a bottom of the contact hole being one of the sacrificial layers;
forming a first spacer layer on a sidewall and the bottom of the contact hole;
removing the first spacer layer on the bottom of the contact hole;
removing a portion of the one of the sacrificial layers to form a first open space in the one of the sacrificial layers;
filling a conductive material into the first open space resulted from the removed portion of the one of the sacrificial layers to form a conductive pad of the respective contact structure;
filling the conductive material into the contact hole to form the respective contact structure.

3. The method of claim 2, wherein the first spacer layer on the sidewall of the contact hole is kept during the removing of the first spacer layer on the bottom of the contact hole.

4. The method of claim 2, wherein the first spacer layer includes silicon oxide and the conductive material includes tungsten.

5. The method of claim 2, wherein the forming the gate line trenches includes:
forming the gate line trenches in the array region and in the contact region during the formation of the contact holes, wherein the gate line trenches and the contact holes are formed under a same etching process in which a same number of etching steps is used in the formation of a contact hole with a maximum depth among the contact holes and the formation of the gate line trenches.

6. The method of claim 2, further comprising:
before forming the first spacer layer,
filling the gate line trenches and the contact holes with a sacrificial material; and
removing the sacrificial material inside the contact holes in the contact region.

7. The method of claim 6, wherein the sacrificial material includes poly silicon.

8. The method of claim 6, wherein the replacing the sacrificial layers with the gate layers includes:
removing the sacrificial material inside the gate line trenches in the contact region;
removing, through the gate line trenches in the contact region, the sacrificial layers adjacent to the gate line trenches in the contact region, until all the conductive pads of the contact structures are open for connecting the gate layers; and
filling the conductive material into second open spaces resulted from the removed sacrificial layers to form a first portion of the gate layers so that the first portion of the gate layers electrically connects to the conductive pads of the contact structures.

9. The method of claim 8, wherein at least a portion of the sacrificial layers underneath the conductive pads of the contact structures is kept during the removing of the sacrificial layers adjacent to the gate line trenches in the contact region.

10. The method of claim 8, further comprising:
removing the sacrificial material inside the gate line trenches in the array region;
removing, through the gate line trenches in the array region, the sacrificial layers in the array region; and
filling the conductive material into third open spaces resulted from the removed sacrificial layers in the array region to form a second portion of the gate layers so that the second portion of the gate layers electrically connects to the first portion of the gate layers.

11. The method of claim 10, further comprising:
filling the gate line trenches in the array region and in the contact region with one or more dielectric materials.

12. The method of claim 11, wherein the filling the gate line trenches includes:
for each gate line trench,
forming a second spacer layer on a sidewall and a bottom of the respective gate line trench; and
filling a dielectric material into the respective gate line trench.

13. The semiconductor device of claim 1, wherein a ratio between a critical dimension of each of the contact structures and a critical dimension of each of the gate line trenches is less than or equal to a threshold.

14. The semiconductor device of claim 13, wherein the threshold is between 0.5 and 1.5.

15. A semiconductor device, comprising:
a substrate;
a stack of alternative layers including insulating layers and gate layers that are stacked alternatively over the substrate, the stack of alternative layers including an array region and a contact region;
a plurality of channel structures disposed through the stack of alternative layers in the array region, each channel structure forming a stack of transistors in a series configuration with the gate layers being gate terminals of the stack of transistors;
a plurality of contact structures disposed in the contact region, each contact structure electrically connecting to one of the gate layers; and
a plurality of gate line trenches disposed through the stack of alternative layers in the array region and in the contact region, the gate line trenches being formed during the formation of the plurality of contact structures in the contact region.

16. The semiconductor device of claim 15, further comprising:
one or more sacrificial layers underneath the plurality of contact structures.

17. The semiconductor device of claim 15, wherein each of the plurality of contact structures includes a first spacer layer on a sidewall of the respective contact structure.

18. The semiconductor device of claim 15, wherein each of the plurality of gate line trenches includes a second spacer layer on a sidewall of the respective gate line trench.

19. The semiconductor device of claim 15, wherein a ratio between a critical dimension of each of the plurality of contact structures and a critical dimension of each of the plurality of gate line trenches is less than or equal to a threshold.

20. A memory system, comprising:
one or more memory devices and a memory controller that is coupled to and controls the one or more memory devices,
wherein each of the one or more memory devices comprises
a substrate,
a stack of alternative layers including insulating layers and gate layers that are stacked alternatively over the substrate, the stack of alternative layers including an array region and a contact region,
a plurality of channel structures disposed through the stack of alternative layers in the array region, each channel structure forming a stack of transistors in a series configuration with the gate layers being gate terminals of the stack of transistors,
a plurality of contact structures disposed in the contact region, each contact structure electrically connecting to one of the gate layers, and
a plurality of gate line trenches disposed through the stack of alternative layers in the array region and in the contact region, the gate line trenches being formed during the formation of the plurality of contact structures in the contact region.
